(19) United States
(12) Patent Application Publication
(10) Pub. No.: US 2011/0135427 A1
(43) Pub. Date: Jun. 9, 2011

(54) METHOD FOR TRANSFERRING TARGET OBJECT AND APPARATUS FOR PROCESSING TARGET OBJECT

(75) Inventor: Hiromitsu SAKAUE, Nirasaki City (JP)

(73) Assignee: TOKYO ELECTRON LIMITED, Tokyo (JP)

(21) Appl. No.: 12/957,915

(22) Filed: Dec. 1, 2010

(30) Foreign Application Priority Data
Dec. 3, 2009 (JP) 2009-275615

(51) Int. Cl. H01L 21/677

(52) U.S. Cl. 414/217; 414/805

(57) ABSTRACT

A method, for transferring target objects in an apparatus wherein a processing chamber processes the n-number of target objects simultaneously (n being an integer not smaller than 2), and a transfer device holds at least the n+1 number of target objects, includes the steps of (a) unloading the n-number of unprocessed target objects from a load-lock chamber to a transfer chamber by using the transfer device, (b) unloading at least one of processed target objects from the processing chamber to the transfer chamber by the transfer device and (c) loading at least one of the unprocessed target objects held by the transfer device from the transfer chamber to the processing chamber. The steps (b) and (c) are repeated until all of the processed target objects in the processing chamber is exchanged with the unprocessed target objects held by the transfer device.

### CROSS-REFERENCE TO RELATED APPLICATIONS

This application claims priority to Japanese Patent Application No. 2009-275615 filed on Dec. 3, 2009, the entire contents of which are incorporated herein by reference.

### FIELD OF THE INVENTION

The present invention relates to a method for transferring a processing target object and an apparatus for processing the target object.

### BACKGROUND OF THE INVENTION

In a manufacturing process of an electronic device, a processing target object is used, and various processes such as film formation, etching and the like are performed on the target object. For example, in a manufacturing process of a semiconductor integrated circuit device apparatus, a semiconductor wafer is used as the target object, and various processes such as film formation, etching and the like are performed on the semiconductor wafer. In general, such processes are carried out in separate processing apparatuses. For example, a film forming process is performed in a film forming apparatus having a film forming chamber, while an etching process is performed in an etching processing apparatus having an etching processing chamber.

Recently, in order to achieve a processing integration and reduce the foot print that is caused by an increase in the number of the processing apparatus, there has been widely used a multi chamber (cluster tool) type processing apparatus for processing a processing target object in which a plurality of processing chambers is disposed around a transfer chamber. A typical example of the multi chamber type processing apparatus for processing a processing target object is described in, e.g., Japanese Patent Application Publication No. 2005-64509 (corresponding to U.S. Patent Publication No. 20050036855).

Further, Japanese Patent Application Publication Nos. 2005-64509 and 2004-282002 (corresponding to U.S. Patent Publication No. 20090169344) describe a transfer device using a multi-joint robot that is used for transferring the target object between the transfer chamber and the processing chambers.

Meanwhile, in various processes such as film formation, etching and the like, extensive efforts have been devoted to reduce the processing time in order to increase the productivity.

However, once the reduction in the processing times of the respective processes is achieved, a rate control factor for the time required for overall processing of a processing target object in the multi chamber type apparatus is changed from the process rate control to the transfer rate control. For that reason, even if each of the processing times is substantially reduced, the increase in the productivity is limited.

### SUMMARY OF THE INVENTION

In view of the above, the present invention provides a method for transferring a processing target object and an apparatus for processing the target object, capable of solving the problem in which the increase in the productivity is limited even if the processing time of each process is reduced.

In accordance with an aspect of the present invention, there is provided a method for transferring processing target objects in an apparatus for processing the target objects, the apparatus having: a transfer chamber where a transfer device for transferring the target objects is provided; a processing chamber, provided around the transfer chamber, for processing therein the target objects; and a load-lock chamber, provided around the transfer chamber, for converting the environment around the target objects accommodated therein to an environment close to the environment inside the transfer chamber, wherein the processing chamber is configured to process the n-number of target objects simultaneously (n being an integer greater than or equal to 2), and the transfer device is configured to hold at least the n+1 number of target objects.

The method includes the steps of: (a) unloading the n-number of unprocessed target objects from the load-lock chamber to the transfer chamber by using the transfer device; (b) unloading at least one of processed target objects from the processing chamber to the transfer chamber by using the transfer device; and (c) loading at least one of the unprocessed target objects held by the transfer device from the transfer chamber to the processing chamber by using the transfer device, wherein the steps (b) and (c) are repeated until the processed target objects accommodated in the processing chamber are completely exchanged with the unprocessed target objects held by the transfer device.

In accordance with another aspect of the present invention, there is provided an apparatus for processing target objects, including: a loader unit where a loading/unloading device for loading/unloading the target objects is provided; a transfer chamber where a transfer device for transferring the target objects is provided; a processing chamber, provided around the transfer chamber, for processing therein the target objects; a load-lock chamber, provided between the loader unit and the transfer chamber, for converting the environment around the target objects accommodated therein to an environment close to the environment either inside the loader unit or inside the transfer chamber, wherein the processing chamber is configured to process the n-number of target objects simultaneously (n being an integer greater than or equal to 2), and the transfer device and the loading/unloading device are configured to hold at least the n+1 number of target objects; and a process controller.

The process controller performs the steps of: (a) unloading the n-number of unprocessed target objects from the load-lock chamber to the transfer chamber by using the transfer device; (b) unloading at least one of processed target objects from the processing chamber to the transfer chamber by using the transfer device; (c) loading at least one of the unprocessed target objects from the transfer chamber to the processing chamber by using the transfer device; (d) repeating the steps (b) and (c) until the n-number of the processed target objects accommodated in the processing chamber are completely exchanged with the n-number of the unprocessed target objects held by the transfer device; (e) loading the n-number of the processed target objects from the transfer chamber to the load-lock chamber by using the transfer device; (f) holding the n-number of additional unprocessed target objects different from the unprocessed target objects by using the loading/unloading device; (g) unloading at least one of the processed target objects from the load-lock chamber to the loader unit by using the loading/unloading device; (h) loading at least one of the additional unprocessed target objects from the loader unit to the load-lock chamber by using the loading/unloading device; and (i) repeating the steps (g) and (h) until the n-number of the processed target objects accommodated in the load-lock chamber are completely exchanged with the additional unprocessed target objects held by the loading/unloading device.

### BRIEF DESCRIPTION OF THE DRAWINGS

The objects and features of the present invention will become apparent from the following description of embodiments, given in conjunction with the accompanying drawings, in which:

FIG. 1 is a top view showing an example of an apparatus for processing a processing target object which can perform a method for transferring the target object in accordance with an embodiment of the present invention;

FIG. 2 is a cross sectional view showing an example of a load-lock chamber in accordance with the embodiment of the present invention;

FIG. 3 is a perspective view showing an example of a transfer device capable of performing the method for transferring the target object in accordance with the embodiment of the present invention;

FIG. 4 is a timing diagram, wherein each of (A) and (B) of FIG. 4 shows an example of the method for transferring the target object in accordance with the embodiment of the present invention and a comparative example of the transferring method;

FIG. 5A is a top view showing an operation state of the transfer device in a step 1 shown in (A) of FIG. 4;

FIG. 5B is a top view showing an operation state of the transfer device in a step 3 shown in (A) of FIG. 4;

FIGS. 6A to 6H are cross sectional views, each showing a specific example of the exchange of a processed wafer and an unprocessed wafer; and

FIGS. 7A and 7B are top views, each showing an example of an exchanging operation of a loading/unloading device.

### DETAILED DESCRIPTION OF THE EMBODIMENT

An embodiment of the present invention will be described with reference to the accompanying drawings which form a part hereof. Further, like reference numerals will be given to like parts throughout all the drawings.

In this example, a multi chamber (cluster tool) type semiconductor manufacturing apparatus using a semiconductor wafer as a processing target object is employed as an example of the apparatus for processing the target object.

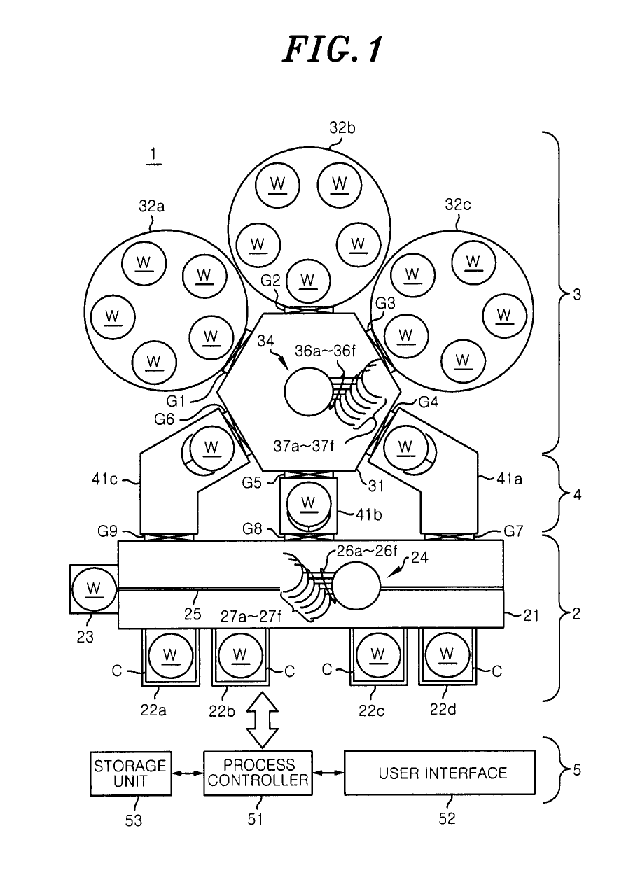

As shown in FIG. 1, a semiconductor manufacturing apparatus 1 includes a loader module 2 for loading and unloading the semiconductor wafer between the semiconductor manufacturing apparatus 1 and the outside, a processing unit 3 for processing the wafer W, a load-lock unit 4 for loading and unloading the wafer W between the loader module 2 and the processing unit 3, and a control unit 5 for controlling the semiconductor manufacturing apparatus 1.

The loader module 2 has a loader unit 21. The pressure inside the loader unit 21 can be controlled to be set to the atmospheric pressure or near the atmospheric pressure, e.g., a slight positive pressure with respect to the outside atmospheric pressure. In this example, the loader unit 21 has a rectangular shape when seen from the top, the rectangular shape having longer sides and shorter sides perpendicular to the longer sides. The processing unit 3 is disposed to face one of the longer sides of the rectangle via the load-lock unit 4. One or more loading ports 22, each for mounting thereon a carrier C which is either accommodating wafers W therein or empty, are provided at the other one of the longer sides. In this example, four loading ports 22a to 22d are provided. Each of the loading ports 22a to 22d is provided with a shutter (not shown). When the carrier C is mounted on one of the loading ports 22a to 22d, the shutter is opened so that the inner space of the carrier C and that of the loader unit 21 can communicate with each other while preventing intrusion of air from outside. An orienter 23 for aligning the direction of the wafers W unloaded from the carrier C is provided at a shorter side of the rectangle.

The processing unit 3 includes a transfer chamber 31 and a plurality of processing chambers 32 for processing the wafers W. In this example, a single transfer chamber 31 and three processing chambers 32a to 32c arranged around the transfer chamber 31 are provided. Each of the processing chambers 32a to 32c is configured as a vacuum chamber having an inner space that can be evacuated to a predetermined vacuum level, and a predetermined vacuum processing such as film formation, etching or the like can be performed therein. The processing chambers 32a to 32c are connected to the transfer chamber 31 through gate valves G1 to G3, respectively.

Moreover, each of the processing chambers 32a to 32c is configured to process a plurality of wafers simultaneously. In this particular example, the number of wafers W that can be processed simultaneously (hereinafter, referred to as “the simultaneously processible number of wafers W”) is set to five.

The load-lock unit 4 has a plurality of load-lock chambers 41. In this example, three load-lock chambers 41a to 41c are arranged around the single transfer chamber 31. Each of the load-lock chambers 41a to 41c is configured as a vacuum chamber having an inner space that can be evacuated to a predetermined vacuum level. The pressure in each of the load-lock chambers 41a to 41c can be changed between the predetermined vacuum level and the atmospheric pressure (or near the atmospheric pressure), so that the environment around the wafer W can be same as or close to that inside the transfer chamber 31. The load-lock chambers 41a to 41c are connected to the transfer chamber 31 through gate valves G4 to G6 and also connected to the loader unit 21 through gate valves G7 to G9, respectively.

Besides, each of the load-lock chambers 41a to 41c can accommodate therein a plurality of wafers W. In order to accommodate a plurality of wafers W, each of the load-lock chambers 41a to 41c can have a structure in which a plurality of wafers W is arranged on top of one another at different heights, as shown in FIG. 2, for example. In this example, the number of wafers W that can be accommodated is set to be equal to the number of wafers W that can be processed simultaneously in each of the processing chambers 32a to 32c. Specifically, the number of wafers W that can be accommodated (hereinafter, referred to as “the accommodable number of wafers W”) in each of the load-lock chambers 41a to 41c is set to five.

The control unit 5 has a process controller 51, a user interface 52, and a storage unit 53. The process controller 51 has a microprocessor (computer). The user interface 52 has a keyboard through which an operator inputs commands to manage the semiconductor manufacturing apparatus 1, a display for visually displaying an operation status of the semiconductor manufacturing apparatus 1 or the like. The storage unit 53 stores therein control programs for implementing various processes performed by the semiconductor manufacturing apparatus 1 under the control of the process controller 51 and recipes for executing processes in the semiconductor manufacturing apparatus 1 in accordance with various data and process conditions. The recipes are stored in a storage medium of the storage unit 53. The storage medium may be a computer readable storage medium, e.g., a hard disk, or a portable storage medium such as a CD-ROM, a DVD, a flash memory or the like. Alternatively, the recipes may be appropriately transmitted from another device via, e.g., a dedicated transmission line. A certain recipe is retrieved from the storage unit 53 under an instruction inputted through the user interface 52 and executed by the process controller 51, so that a desired process is performed in the semiconductor manufacturing apparatus 1 under the control of the process controller 51.

A loading/unloading device 24 is provided inside the loader unit 21. The loading/unloading device 24 performs loading and unloading of the wafers W as well as transferring them between the carrier C and the loader unit 21, between the loader unit 21 and the orienter 23, and between the loader unit 21 and the load-lock chambers 41a to 41c. The loading/unloading device 24 is configured to travel on a rail 25 extending along the longer side direction of the loader unit 21.

A transfer device 34 is provided inside the transfer chamber 31. The transfer device 34 performs loading and unloading of the wafers W as well as transferring them between the load-lock chambers 41a to 41c and the transfer chamber 31 and between the transfer chamber 31 and the processing chambers 32a to 32c. In this example, the transfer device 34 is disposed substantially at the center of the transfer chamber 31.

In addition, the loading/unloading device 24 has a plurality of multi-joint arms 26, each having a hand 27 at the leading end thereof. The total number of the multi-joint arms 26 is set to be larger than the number of wafers W that can be accommodated in the load-lock chambers 41a to 41c while the number of wafers W that are exchanged simultaneously (the exchange number) is taken into consideration.

For example, suppose the accommodable number of wafers W in each of the load-lock chambers 41a to 41c is set to “m”, and the loading/unloading device 24 exchanges the wafer W one by one. Then, the total number of multi-joint arms 26 is set as follows:

the total number of multi-joint arms 26=m+1 (“1” is the exchange number).

In case that the loading/unloading device 24 exchanges two wafers W simultaneously, the total number of multi-joint arms 26 is set as follows:

the total number of multi-joint arms 26=m+2 (“2” is the exchange number).

In this particular example, the accommodable number of wafers W in each of the load-lock chambers 41a to 41c is set to “5” as described above and the exchange number is set to “1”. Therefore, the total number of multi-joint arms 26 becomes “6 (26a to 26f)” and, thus, the total number of hands 27 becomes “6 (27a to 27f)”.

In addition, the transfer device 34 of this example has a plurality of extensible, contractible and rotatable transfer arms 36, each having a pick 37 at the leading end thereof. The total number of the transfer arms 36 is set to be larger than the simultaneously processible number of wafers W in each of the processing chambers 32a to 32c while the exchange number is taken into consideration.

For example, suppose the simultaneously processible number of wafers W in each of the processing chambers 32a to 32c is set to “n”, and the transfer device 34 exchanges the wafers W one by one. Then, the total number of transfer arms 36 is set as follows:

the total number of transfer arms 36=n+1 (“1” is the exchange number).

In case that the transfer device 34 exchanges two wafers W simultaneously, the total number of transfer arms 36 is set as follows:

the total number of transfer arms 36=n+2 (“2” is the exchange number).

In this particular example, the simultaneously processible number of wafers W in each of the processing chambers 32a to 32c is set to “5” as described above, and the exchange number is set to “1”. Thus, the total number of the transfer arms 36 becomes “6 (36a to 36f)” and, thus, the total number of the picks 37 becomes “6 (37a to 37f)”.

Hereinafter, an example of a method for transferring the target object in accordance with the embodiment of the present invention will be described.

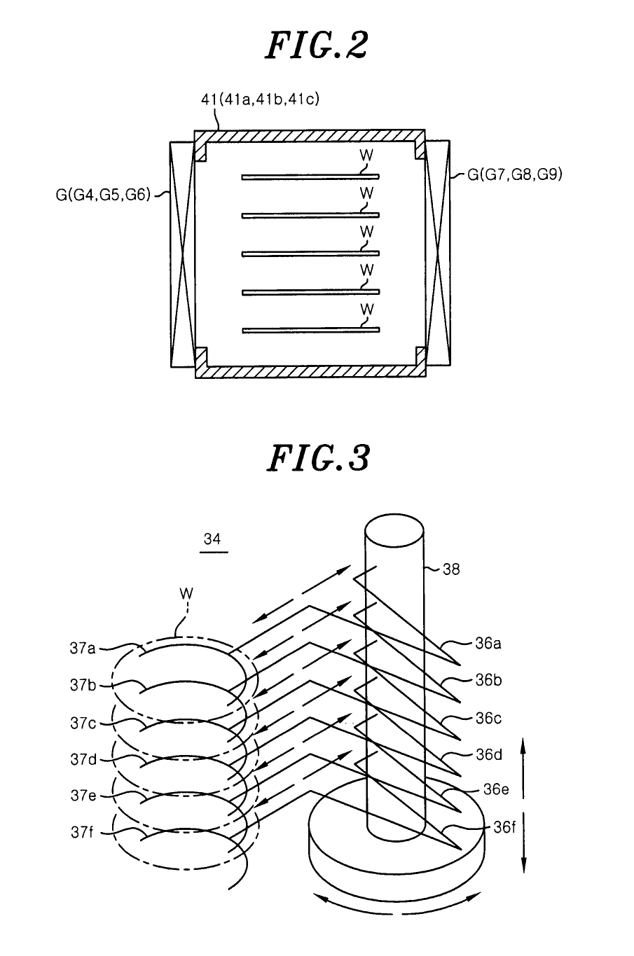

FIG. 3 is a perspective view showing an example of the transfer device 34 capable of performing the method for transferring the target object in accordance with the embodiment of the present invention. FIG. 3 shows a detailed configuration of the transfer device 34 shown in FIG. 1.

As shown in FIG. 3, the transfer device 34 has a main body 38 configured to be vertically movable and rotatable. Six transfer arms 36a to 36f which can be independently extended and contracted in a horizontal direction are attached to the main body 38. The transfer arms 36a to 36f have, at the leading ends thereof, the picks 37a to 37f for holding the wafers W.

When unprocessed wafers W are received from one of the load-lock chambers 41a to 41c, not all of the picks 37a to 37f are used to hold the unprocessed wafers W. Specifically, at least one of the picks 37a to 37f remains to be empty. In this example, the pick 37f remains to be empty, and the empty pick 37f is used to receive one of processed wafers W from one of the processing chambers 32a to 32c. Further, in this example, one pick 37f remains to be empty because the exchange number is one. However, when the exchange number is two, two picks are required to be left empty.

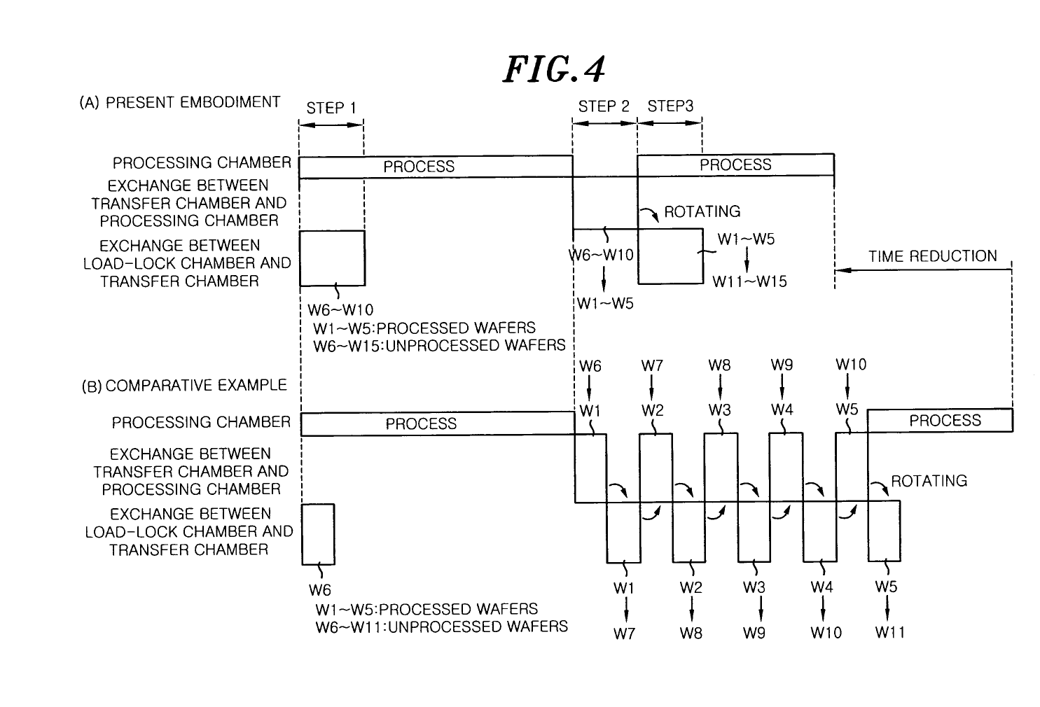

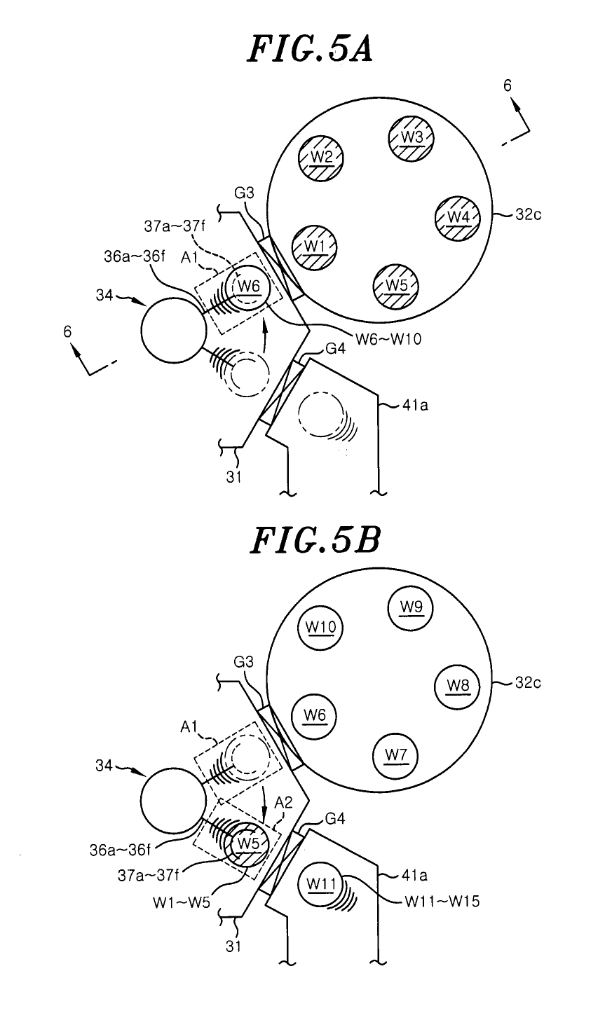

FIG. 4 is a timing diagram, wherein each of (A) and (B) of FIG. 4 shows an example of the method for transferring the target object in accordance with the embodiment of the present invention and a comparative example of the transferring method; FIG. 5A is a top view showing an operation state of the transfer device 34 in step 1 shown in (A) of FIG. 4; and FIG. 5B is a top view showing an operation state of the transfer device 34 in step 3 shown in (A) of FIG. 4.

As shown in (A) of FIG. 4, in the present embodiment, while the wafers W are being processed in the processing chambers 32a to 32c, a plurality of, e.g., five, unprocessed wafers W, is loaded from one of the load-lock chambers 41a to 41c into the transfer chamber 31 by the transfer device 34 and held by the picks 37a to 37e. Next, the transfer device 34 is rotated to be located at an access position of a processing chamber where the exchange of wafers W is required among the processing chambers 32a to 32c (step 1). Such operation state is shown in FIG. 5A. In the example of FIG. 5A, unprocessed wafers W6 to W10 unloaded from the load-lock chambers 41a are held by the picks 37a to 37e and, then, the transfer device 34 is rotated to be located at an access position A1 of the processing chamber 32c.

Next, when the processing of wafers W (W1 to W5) in, e.g., the processing chamber 32c among the processing chambers 32a to 32c, is completed, the processed wafer W1 is unloaded from the processing chamber 32c into the transfer chamber 31 by the transfer device 34 and held by the empty pick 37f.

Thereafter, one of the unprocessed wafers W6 to W10 which are held by the respective picks 37a to 37e is loaded from the transfer chamber 31 into the processing chamber 32c by the transfer device 34.

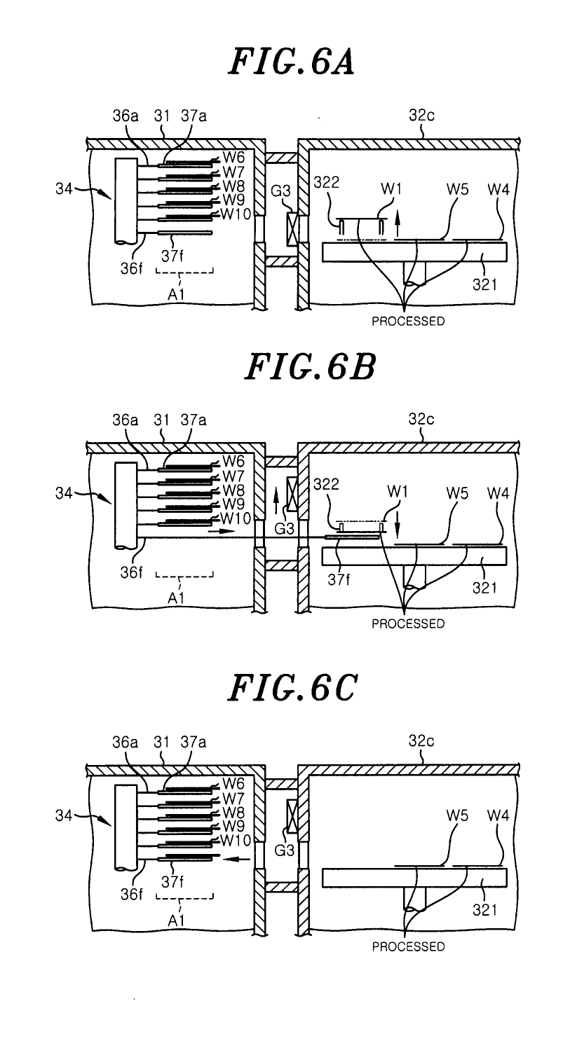

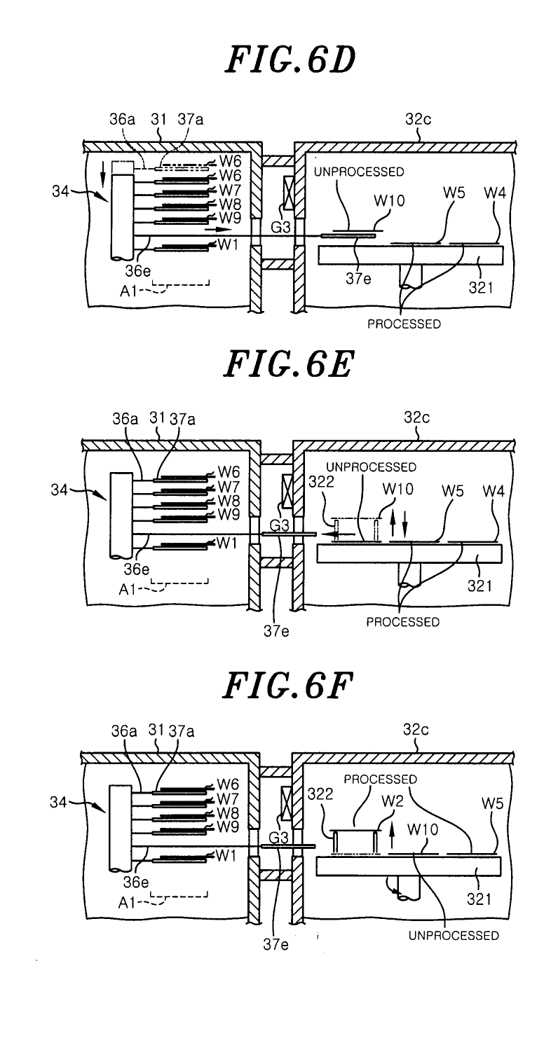

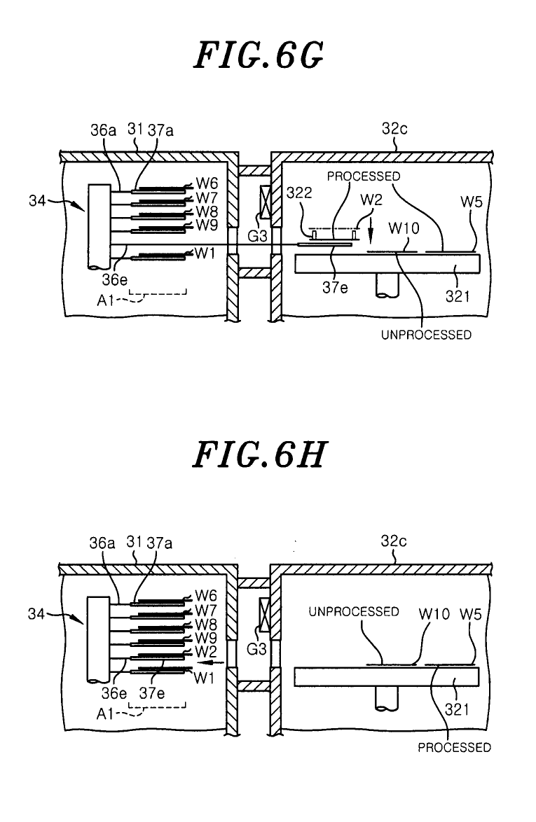

Each of FIGS. 6A to 6H shows a specific example of the exchange of processed wafers and unprocessed wafers between the transfer chamber 31 and the processing chamber 32c. The cross sections shown in FIGS. 6A to 6H correspond to those taken along line 6-6 shown in FIG. 5A.

First, as shown in FIG. 6A, the unprocessed wafers W6 to W10 are held by the picks 37a to 37e, and the transfer device 34 is rotated to the access position A1, i.e., in the example of FIG. 6A, the position directly facing the gate valve G3. Upon completion of the processing in the processing chamber 32c, lift pins 322 are raised from a susceptor 321 so as to separate the processed wafer W1 from the susceptor 321.

Then, as shown in FIG. 6B, the gate valve G3 is opened so that the inner space of the transfer chamber 31 can communicate with that of the processing chamber 32c. Thereafter, a lowermost transfer arm 36f is extended, and the empty pick 37f is positioned below the processed wafer W1. Then, the lift pins 322 are lowered, and the processed wafer W1 is accordingly lowered to be held on the empty pick 37f.

Next, as shown in FIG. 6C, the transfer arm 36f is contracted so that the pick 37f is returned back to the rotation position (original position).

Then, as shown in FIG. 6D, the transfer device 34 is vertically moved down and positioned to directly face the gate valve G3, and a second lowermost transfer arm 36e is extended so that the pick 37e on which the unprocessed wafer W10 is mounted is positioned above the susceptor 321.

Thereafter, as shown in FIG. 6E, the lift pins 322 are raised, and the unprocessed wafer W10 is loaded on the lift pins 322. Next, the transfer arm 36e is contracted. At this time, it is unnecessary to return the pick 37e back to the rotation position (original position). Preferably, the pick 37e may be returned to an intermediate position, where the pick 37e does not affect the vertical movement of the wafer. Accordingly, the wafer exchange time can be reduced compared to the case of returning the pick 37e back to the rotation position (original position). Thereafter, the lift pins 322 are lowered, and the unprocessed wafer W10 is mounted on the susceptor 321.

Next, as shown in FIG. 6F, the processed wafer W2 is moved to the position directly facing the access position A1 by revolving the susceptor 321. Then, the lift pins 322 are raised from the susceptor 321, so that the processed wafer W2 is separated from the susceptor 321.

Subsequently, as shown in FIG. 6G, the transfer arm 36e is extended, and the empty pick 37e is positioned below the processed wafer W2. Thereafter, the lift pins 322 are lowered, and the processed wafer W2 is accordingly lowered to be held on the pick 37e.

Then, as shown in FIG. 6H, the transfer arm 36e is contracted, and the pick 37e is returned to the rotation position (original position).

Such exchanging operation is repeated until the processed wafers W1 to W5 accommodated in the processing chamber 32c are exchanged completely with the unprocessed wafers W6 to W10 held by the picks 37a to 37e (step 2). In the present embodiment, the step 2 is executed simply by extending/contracting the transfer arms 36a to 36f and vertically moving the transfer device 34 without rotating the transfer device 34 from the access point A1.

In the present embodiment, the processed wafers W1 to W5 are exchanged with the unprocessed wafers W6 to W10 in the above manner.

Next, the wafers W6 to W10 are processed in the processing chamber 32c after the exchange of the wafers W is completed. While this process is being carried on, the processed wafers W1 to W5 in the transfer chamber 31 are exchanged with unprocessed wafers W11 to W15 in one of the load-lock chambers 41a to 41c, i.e., the load-lock chamber 41a in the this particular example, by using the transfer device 34 (step 3). At this time, as shown in FIG. 5B, the transfer device 34 having the pick 37a remaining empty and the picks 37b to 37f on which the processed wafers W1 to W5 are respectively mounted is rotated from the access position A1 to an access position A2 of the load-lock chamber 41a. Thereafter, the processed wafers W1 to W5 are exchanged with the unprocessed wafers W11 to W15 by using the transfer device 34.

Even though there is a difference between the load-lock chamber 41a and the susceptor 321, wherein a plurality of wafers W is arranged on respective planes vertically separated on top of one another in the load-lock chamber 41a while a plurality of wafers W is arranged on a horizontal plane in the susceptor 321, the exchanging operation of wafers W between the transfer chamber 31 and the load-lock chamber 41a can be carried out in the same manner as that described in, e.g., FIGS. 6A to 6H regardless of such difference.

Specifically, first, the unprocessed wafer W11 is transferred to the empty pick 37a to be held thereon, and one of the processed wafers W1 to W5, e.g., the wafer W5, is transferred to a mounting position of the load-lock chamber 41a which has become empty by transferring the wafer W11 to the pick 37a. Thereafter, the unprocessed wafer W12 is transferred to the pick 37b which has become empty by transferring the processed wafer W5 to the mounting position. By repeating the above-described operations, the processed wafers W1 to W5 are sequentially exchanged with the unprocessed wafers W11 to W15. In the present embodiment, as shown in FIG. 5B, such exchanging operation is performed simply by extending/contracting the transfer arms 36a to 37f and vertically moving the transfer device 34 without rotating the transfer device 34 from the access position A2.

In such target object transfer method of the present embodiment, each of the wafer exchange operation between the transfer chamber 31 and anyone of the processing chambers 32a to 32c and that between the transfer chamber 31 and anyone of the load-lock chamber 41a to 41c is carried out collectively on the basis of the number of wafers simultaneously processible in anyone of the processing chambers 32a to 32c.

Accordingly, it is possible to carry out such wafer exchange therebetween in much shorter time as compared with the comparative examples such as the one shown in (B) of FIG. 4 wherein the exchanging operation of the processed wafers in the processing chambers 32a to 32c with the unprocessed wafers in the load-lock chambers 41a to 41c is carried out, e.g., one by one by rotating the transfer device back and forth between the processing chambers 32a to 32c and the load-lock chambers 41a to 41c each time.

Hence, in accordance with the method for transferring the target object of the present embodiment, it is possible to solve the problem in which the increase in the productivity is limited even if the processing time is reduced.

As described above, when the exchanging operation of the processed wafers and the unprocessed wafers is carried out, e.g., one by one by rotating the transfer device back and forth, the exchange time is increased. Thus, it is preferable to allow the loading/unloading device 24 provided in the loader unit 21 to perform the exchanging operation in a same manner as that of the transfer device 34.

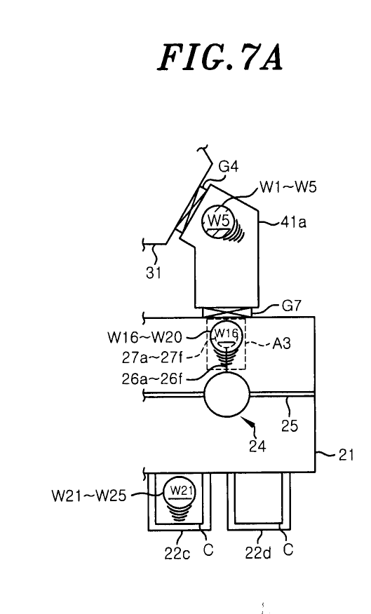

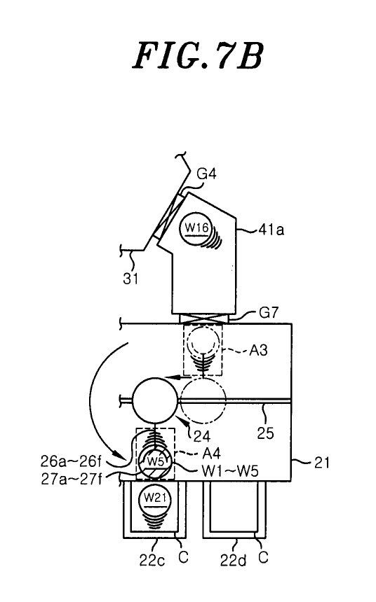

FIGS. 7A and 7B show examples of the exchanging operation of the loading/unloading device 24.

FIG. 7A shows an example in which unprocessed wafers W16 to W20 unloaded from the carrier C are held by the picks 27a to 27e except the lowermost pick 27f among the picks 27a to 27f of the loading/unloading device 24 and, then, the loading/unloading device 24 is horizontally moved and rotated to an access position A3 of the load-lock chamber 41a.

The unprocessed wafers W16 to W20 held by the picks 27a to 27e are exchanged with the processed wafers W1 to W5 accommodated in the load-lock chamber 41a simply by extending/contracting multi-joint arms 26a to 26f and vertically moving the loading/unloading device 24 without horizontally moving and rotating the loading/unloading device 24 from the access position A3. Such exchanging operation is preferably performed in the same manner as that described in FIGS. 6A to 6H even though there is difference between a type arranging a plurality of wafers W vertically and a type arranging them horizontally.

For example, first, the processed wafer W1 is transferred to the lowermost empty pick 27f to be held thereby. Next, one of the unprocessed wafers W16 to W20, e.g., the unprocessed wafer W16 held by the pick 27e, is transferred to a mounting position of the load-lock chamber 41a which has become empty by transferring the wafer W1 to the pick 27f. Then, the processed wafer W2 is transferred to the pick 27e which has become empty by transferring the unprocessed wafer W16 to the mounting position. By repeating the above-described operations, the processed wafers W1 to W5 accommodated in the load-lock chamber 41a are exchanged with the unprocessed wafers W16 to W20. Such exchanging operation is performed simply by extending/contracting the multi-joint arms 26a to 26f and vertically moving the loading/unloading device 24 without horizontally moving and revolving the loading/unloading device 24 from the access position A3.

The same manner of exchanging operation is also performed between the loading/unloading device 24 and the carrier C.

For example, as shown in FIG. 7B, the loading/unloading device 24 allows the processed wafers W1 to W5 unloaded from the load-lock chamber 41a to be held by the picks 27b to 27f except the uppermost pick 27a among the picks 27a to 27f. Next, the loading/unloading device 24 in such state is horizontally moved along the rail 25 and, then, the multi-joint arms 26a to 26f of the loading/unloading device 24 are rotated to an access position A4 of the carrier C mounted on, e.g., the loading port 22c. Thereafter, an unprocessed wafer W21 is held by the empty pick 27a. Then, one of the processed wafers W1 to W5, e.g., the wafer W5, is transferred to a mounting position of the carrier C which has become empty by transferring the wafer W21 to the pick 27a. Next, an unprocessed wafer W22 is transferred to the pick 27b which has become empty by transferring the processed wafer W5 to the mounting position. By repeating the above-described operations, the processed wafers W1 to W5 are accommodated in the carrier C, and the unprocessed wafers W21˜W25 accommodated in the carrier C are held by the picks 27a to 27e except the lowermost pick 27f among the picks 27a to 27f. Such exchanging operation is performed simply by extending/contracting the multi-joint arms 26a to 26f and vertically moving the loading/unloading device 24 without horizontally moving and rotating the loading/unloading device 24 from the access position A4.

As described above, the time required for the exchanging operation of the loading/unloading device 24 can be reduced by allowing the loading/unloading device 24 to perform the exchanging operation in a same manner as that of the transfer device 34.

The above-described transfer method of the present embodiment is performed by the transfer device 34 and the loading/unloading device 24 under the control of the process controller 51.

Further, the above-embodiment is not the only example of the present invention and the present invention may be variously modified without being limited to the above-described embodiment.

For example, in the above embodiment, the number of the processing chambers 32 and the number of the load-lock chambers 41 are respectively three. However, the number of the processing chambers 32 and the number of the load-lock chambers 41 can be varied.

In addition, the simultaneously processible number of wafers W in the processing chamber 32 is five in the above embodiment; however, it is not limited thereto. When the simultaneously processible number of the wafers W in the processing chamber 32 is set to “n”, n is preferably a integer larger than or equal to two.

Moreover, in the above embodiment, the load-lock chamber 41 is configured to accommodate a plurality of wafers W. However, the load-lock chamber 41 may be modified to accommodate a single wafer W.

In accordance with the embodiment of the present invention, it is possible to provide a method for transferring a processing target object and an apparatus for processing the target object, capable of solving the problem in which the increase in the productivity is limited even if the processing time of each process is reduced.

While the invention has been shown and described with respect to the embodiment, it will be understood by those skilled in the art that various changes and modifications may be made without departing from the scope of the invention as defined in the following claims.

What is claimed is:

1. A method for transferring processing target objects in an apparatus for processing the target objects, wherein the apparatus includes: a transfer chamber where a transfer device for transferring the target objects is provided; a processing chamber, provided around the transfer chamber, for processing therein the target objects; and a load-lock chamber, provided around the transfer chamber, for converting the environment around the target objects accommodated therein to the environment close to that inside the transfer chamber, wherein the processing chamber is configured to process the n-number of target objects simultaneously, wherein n is an integer greater than or equal to 2, and the transfer device is configured to hold at least the n+1 number of target objects, the method comprising the steps of:
(a) unloading the n-number of unprocessed target objects from the load-lock chamber to the transfer chamber by using the transfer device;
(b) unloading at least one of processed target objects from the processing chamber to the transfer chamber by using the transfer device; and
(c) loading at least one of the unprocessed target objects held by the transfer device from the transfer chamber to the processing chamber by using the transfer device,
wherein the steps (b) and (c) are repeated until the processed target objects accommodated in the processing chamber are completely exchanged with the unprocessed target objects held by the transfer device.

2. The method of claim 1, wherein the number of the target objects held by the transfer device is greater than the simultaneously processible number of the target objects in the processing chamber by the simultaneously exchangeable number of the target objects of the transfer device.

3. The method of claim 1, wherein the loading of the processed target objects from the transfer chamber to the load-lock chamber and the unloading of the unprocessed target objects from the load-lock chamber to the transfer chamber are performed while other processing target objects are being processed in the processing chamber.

4. The method of claim 2, wherein the loading of the processed target objects from the transfer chamber to the load-lock chamber and the unloading of the unprocessed target objects from the load-lock chamber to the transfer chamber are performed while other processing target objects are being processed in the processing chamber.

5. An apparatus for processing target objects, comprising:
a loader unit where a loading/unloading device for loading/unloading the target objects is provided;
a transfer chamber where a transfer device for transferring the target objects is provided;
a processing chamber, provided around the transfer chamber, for processing therein the target objects;
a load-lock chamber, provided between the loader unit and the transfer chamber, for converting the environment around the target objects accommodated therein to an environment close to the environment either inside the loader unit or inside the transfer chamber, wherein the processing chamber is configured to process the n-number of target objects simultaneously, wherein n is an integer greater than or equal to 2, and the transfer device and the loading/unloading device are configured to hold at least the n+1 number of target objects; and
a process controller,
wherein the process controller performs: the steps of
(a) unloading the n-number of unprocessed target objects from the load-lock chamber to the transfer chamber by using the transfer device;
(b) unloading at least one of processed target objects from the processing chamber to the transfer chamber by using the transfer device;
(c) loading at least one of the unprocessed target objects from the transfer chamber to the processing chamber by using the transfer device;
(d) repeating the steps (b) and (c) until the n-number of the processed target objects accommodated in the processing chamber are completely exchanged with the n-number of the unprocessed target objects held by the transfer device;
(e) loading the n-number of the processed target objects from the transfer chamber to the load-lock chamber by using the transfer device;
(f) holding the n-number of additional unprocessed target objects different from the unprocessed target objects by using the loading/unloading device;
(g) unloading at least one of the processed target objects from the load-lock chamber to the loader unit by using the loading/unloading device;
(h) loading at least one of the additional unprocessed target objects from the loader unit to the load-lock chamber by using the loading/unloading device; and
(i) repeating the steps (g) and (h) until the n-number of the processed target objects accommodated in the load-lock chamber are completely exchanged with the additional unprocessed target objects held by the loading/unloading device.
